(19) United States
(12) Patent Application Publication
(10) Pub. No.: US 2025/0292968 A1
(43) Pub. Date: Sep. 18, 2025

(54) MULTILAYER CERAMIC CAPACITOR AND CIRCUIT BOARD

(71) Applicant: TAIYO YUDEN CO., LTD., Tokyo (JP)

(72) Inventors: Yoshinari TAKE, Tokyo (JP); Tomoki INOUE, Tokyo (JP); Takeshi SAKASHITA, Tokyo (JP); Takayuki TAKANO, Tokyo (JP); Yuka NAITO, Tokyo (JP); Ryo NAKAGAWA, Tokyo (JP)

(73) Assignee: TAIYO YUDEN CO., LTD., Tokyo (JP)

(21) Appl. No.: 19/077,193

(22) Filed: Mar. 12, 2025

(30) Foreign Application Priority Data
Mar. 14, 2024 (JP) 2024-039556

(51) Int. Cl. H01G 4/30; H01G 4/012; H01G 4/232; H05K 1/18

(52) U.S. Cl. CPC H01G 4/30; H01G 4/012; H01G 4/232; H05K 1/181; H05K 2201/10015

(57) ABSTRACT

One aspect of the present invention is a multilayer ceramic capacitor, including: a cuboid element body having a stack formed with alternating ceramic layers and internal electrodes made primarily of metal, a protective portion covering a surface of the stack, and a plurality of via conductors arranged so as to pass through the ceramic layers in the stacking direction of the stack, electrically connected to the internal electrodes, and having at least one end portion reaching the surface of the protective portion, and a plurality of terminal electrodes arranged on at least a mounting face, which is the face that faces the circuit board when the multilayer ceramic capacitor is mounted on the circuit board, among faces that form the surfaces of the element body, and connected electrically to the via conductors, wherein the element body includes a capacitance forming portion, which is a region in which internal electrodes of different polarities overlap in the stacking direction, and an internal electrode partially facing portion formed by a region in which the internal electrodes of the same polarity overlap in the stacking direction, and the via conductor arranged adjacent to this region, and the thickness Tₚ of the internal electrode partially facing portion in the stacking direction is less than the maximum thickness T₁ of the capacitance forming portion in the stacking direction.

### CROSS-REFERENCE TO RELATED APPLICATIONS

This application claims the benefit of Japanese Application No. 2024-039556, filed Mar. 14, 2024, in the Japanese Patent Office. All disclosures of the document named above are incorporated herein by reference.

### BACKGROUND OF THE INVENTION

### 1. Field of the Invention

Aspects of the present invention relate to a multilayer ceramic capacitor and a circuit board.

### 2. Description of the Related Art

A wide variety of ceramic electronic components are used in high-frequency communication systems, such as in mobile phones. There is a demand for smaller and thinner ceramic electronic components, and multilayer ceramic capacitors are being considered to reduce the size and thickness of these components.

Patent Document 1 discloses a thin, damage-resistant multilayer ceramic capacitor in which via hole electrodes used to electrically connect the internal electrode layers and the terminal electrodes to each other have a void inside. In the multilayer ceramic capacitor disclosed in Patent Document 1, the terminal electrodes are formed on the top surface of the element body, which has a flat shape.

### PRIOR ART DOCUMENTS

### Patent Documents

Patent Document 1:

JP 2020-72263 A

### SUMMARY OF THE INVENTION

### Problem(s) to be Solved by the Invention

In the multilayer ceramic capacitor with via hole electrodes (via conductors) disclosed in Patent Document 1, there is a large difference in thermal expansion coefficient between the via conductors, which are made primarily of metal, and the ceramic layer in contact with them. Therefore, cracks may appear between the via conductors and the ceramic layer due to the difference in expansion or contraction between the via conductors and the ceramic layer during firing in the manufacturing process or when large temperature changes occur during use. If these cracks expand and reach the interface between the internal electrodes in contact with the ceramic layer and the via conductors connected to them, they cause a poor connection with the internal electrode, leading to a decrease in capacitance.

It is an object of the present invention to solve this problem by providing a thin multilayer ceramic capacitor with suppressed electrostatic capacitance degradation, and a circuit board on which this multilayer ceramic capacitor has been mounted.

### Means for Solving the Problem

As a result of extensive research conducted to solve this problem, the present inventors discovered that this object could be achieved by making the element body thinner in the vicinity of the via conductors relative to other portions, in a multilayer ceramic capacitor in which the internal electrodes are electrically connected to each other via conductors. The present invention is a product of this discovery.

Specifically, a first aspect of the present invention that solves this problem is a multilayer ceramic capacitor, comprising: a stack formed with alternating ceramic layers and internal electrodes made primarily of metal, a cuboid element body having a protective portion covering a surface of the stack, and a plurality of via conductors arranged so as to pass through the ceramic layers in the stacking direction of the stack, electrically connected to the internal electrodes, and having at least one end portion reaching the surface of the protective portion, and a plurality of terminal electrodes arranged on at least a mounting face, which is the face that faces the circuit board when the multilayer ceramic capacitor is mounted on the circuit board, among faces that form the surfaces of the element body, and connected electrically to the via conductors, wherein the element body includes a capacitance forming portion, which is a region in which internal electrodes of different polarities overlap in the stacking direction, and an internal electrode partially facing portion formed by a region in which the internal electrodes of the same polarity overlap in the stacking direction and the via conductor arranged adjacent to this region, the thickness Tₚ of the internal electrode partially facing portion in the stacking direction is less than the maximum thickness T₁ of the capacitance forming portion in the stacking direction.

A second aspect of the present invention that solves this problem is a circuit board carrying the multilayer ceramic capacitor according to the first aspect.

### Effect of the Invention

Aspects of the present invention are able to provide a thin multilayer ceramic capacitor with suppressed electrostatic capacitance degradation, and a circuit board carrying this multilayer ceramic capacitor.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic diagram (perspective view) showing the configuration of the multilayer ceramic capacitor in the first embodiment of the present invention.

FIG. 2 is a cross-sectional view (LT cross-sectional view) from A-A in FIG. 1.

FIG. 3A is a schematic diagram (LT cross-sectional view) showing an example of another shape for the internal electrode partially facing portion.

FIG. 3B is a schematic diagram (LT cross-sectional view) showing an example of another shape for the internal electrode partially facing portion.

FIG. 4 is a diagram used to explain the step of determining whether the thickness Tₚ in the stacking direction of the internal electrode partially facing portion in a multilayer ceramic capacitor is less than the maximum thickness T₁ in the stacking direction of the capacitance forming portion.

FIG. 5 is a schematic diagram (LT cross-sectional view) showing the configuration of the multilayer ceramic capacitor in the second embodiment of the present invention.

FIG. 6 is a schematic diagram (LT cross-sectional view) showing the configuration of the multilayer ceramic capacitor in the third embodiment of the present invention.

FIG. 7 is a schematic diagram (perspective view) showing the configuration of the multilayer ceramic capacitor in the fourth embodiment of the present invention.

### DETAILED DESCRIPTION OF THE EMBODIMENTS

The configuration and effects of the present invention will now be explained with technical concepts and with reference to the drawings. The mechanism of action includes conjecture, but correctness or incorrectness of this conjecture does not limit the present invention.

### Multilayer Ceramic Capacitor

### First Embodiment

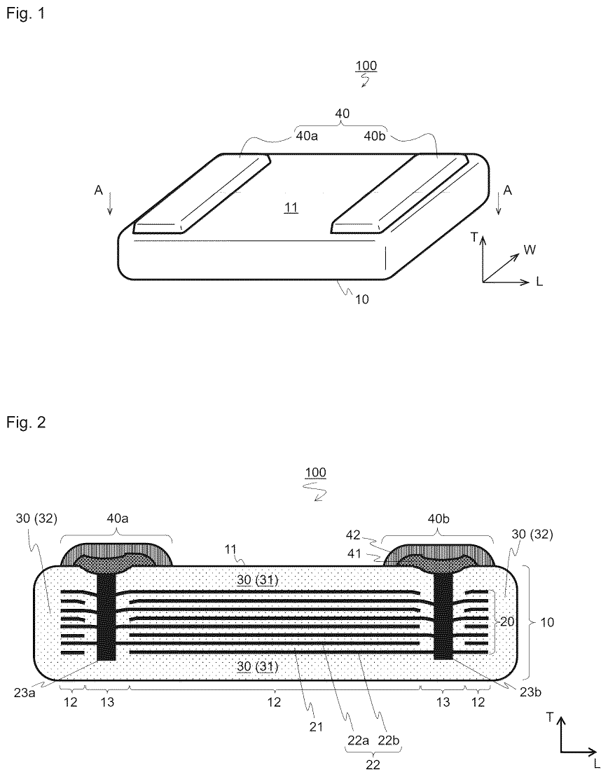

An embodiment of a multilayer ceramic capacitor related to the first aspect of the present invention is shown in FIG. 1 and FIG. 2 as the first embodiment. The multilayer ceramic capacitor 100 in the first embodiment has a cuboid shape and has a pair of planes that are orthogonal to each other on three mutually orthogonal axes, namely, the L-axis, which is the length direction, the W-axis, which is the width direction, and the T-axis, which is the height direction. The cuboid is not limited to a cuboid shape defined mathematically, but can be any shape that is recognized as being cuboid when the overall shape is observed. For this reason, objects with rounded edges and corners, curved edges, and surfaces with a small degree of curvature also fall under the category of “cuboid” in the present disclosure. The length (L), width (W), and height (T) dimensions of the ceramic capacitor 100 can each independently take any value.

In an example of dimensions for a multilayer ceramic capacitor 100, the L-direction dimension is 200 μm or more and 2000 μm or less, the W-direction dimension is 100 μm or more and 2000 μm or less, the T-direction dimension is 30 μm or more and 220 μm or less, and the W/L value, which is the ratio of the W-direction dimension to the L-direction dimension, is 0.3 or more and 1.0 or less. Preferably, the L-direction dimension is 400 μm or more and 1200 μm or less, the W-direction dimension is 400 μm or more and 1200 μm or less, the T-direction dimension is 40 μm or more and 150 μm or less, and the W/L value, which is the ratio of the W-direction dimension to the L-direction dimension, is 0.4 or more and 1.0 or less. A T-direction dimension of 100 μm or less is preferred in that it is less likely to impose design constraints on the circuit board on which it is mounted.

In the multilayer ceramic capacitor 100 of the first embodiment, as shown schematically in cross-sectional view in FIG. 2 (LT cross-sectional view), the element body 10 has ceramic layers 21, internal electrodes 22 made primarily of metal, which are alternately stacked in the T direction to form a stack 20, and a protective portion 30 that covers the surfaces of the stack 20. The internal electrodes 22 include internal electrodes 22a of one polarity that are electrically connected to each other, and internal electrodes 22b of a different polarity than internal electrodes 22a that are electrically connected to each other.

On the surfaces of the element body 10, a protective portion 30 is arranged to cover the surfaces of the stack 20. The protective portion 30 includes a cover portion 31 arranged on a plane perpendicular to the T direction, and margin portions 32 arranged on planes perpendicular to the W and L directions.

The element body 10 has a plurality of via conductors 23 arranged so as to pass through the ceramic layers 21 in the stacking direction of the stack 20 and connect electrically to internal electrodes 22, with at least one end reaching the surface of the protective portion 30 (cover portion 31). The via conductors 23 include via conductor 23a electrically connected to internal electrodes 22a and via conductor 23b electrically connected to internal electrodes 22b. The multilayer ceramic capacitor 100 shown in FIG. 1 and FIG. 2 has two via conductors 23, but the number of via conductors in the multilayer ceramic capacitor of the first aspect of the invention is not limited to this example.

The multilayer ceramic capacitor 100 in the first embodiment has a plurality of terminal electrodes 40 electrically connected to via conductors 23 (23a, 23b), which are located at least on the mounting face 11, which is the face being opposite to the circuit board when the multilayer ceramic capacitor is mounted on the circuit board, among the faces forming the surface of the element body 10. The terminal electrodes 40 includes terminal electrode 40a electrically connected to via conductor 23a and terminal electrode 40b electrically connected to via conductor 23b. The multilayer ceramic capacitor 100 shown in FIG. 1 and FIG. 2 has two terminal electrodes 40, but the number of terminal electrodes in the multilayer ceramic capacitor in the first aspect of the invention is not limited to this example.

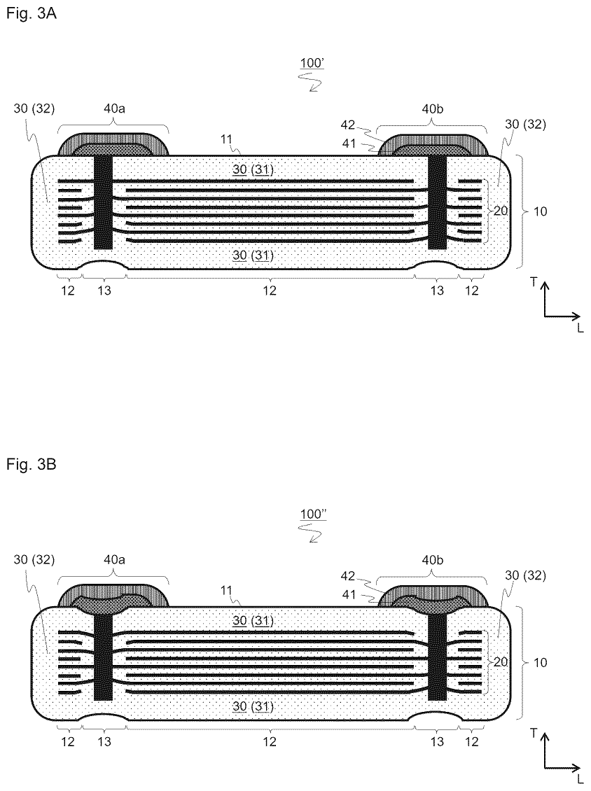

The element body 10 includes capacitance forming portions 12, which are regions in which internal electrodes 22a, 22b with different polarities overlap in the stacking direction, and internal electrode partially facing portions 13 formed by a region in which internal electrodes 22a, 22b with the same polarity overlap in the stacking direction and via conductors 23 arranged in the vicinity of this region. In addition, the thickness Tₚ in the stacking direction of the internal electrode partially facing portions 13 is smaller than the maximum thickness T₁ in the stacking direction of the capacitance forming portions 12. When the element body 10 satisfies Tₚ<T₁, a decrease in the capacitance of the multilayer ceramic capacitor 100 is suppressed. This is probably due to the fact that the element body 10 being thin and the internal electrode partially facing portions 13 being thinner than the capacitance forming portions 12 causes the absolute amount of expansion or contraction in the stacking direction to decrease at the internal electrode partially facing portions 13, and even if there is a difference in the amount of expansion or contraction due to the difference in the coefficient of thermal expansion between the via conductors 23 (23a, 23b) and the ceramic layers 21, this will not lead to the generation of cracks or an expansion of cracks at the interface between them. FIG. 2 shows an example in which only the mounting face 11 located above the internal electrode partially facing portions 13 is recessed among the sides of the stack 20, but the shape of the internal electrode partially facing portions 13 in the multilayer ceramic capacitor in the first aspect of the present invention is not limited to this example. For instance, the face opposite the mounting face 11 may be the only side of the stack 20 that is recessed, as in the multilayer ceramic capacitor 100′ shown in FIG. 3A, or both the mounting face 11 and the face opposite this may be the recessed sides of the stack 20, as in the multilayer ceramic capacitor 100″ shown in FIG. 3B.

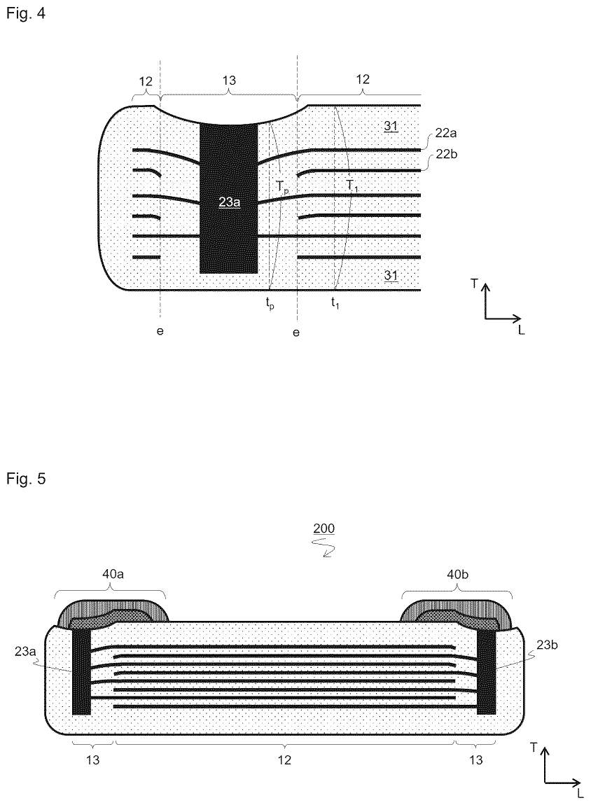

Here, the following process is performed to determine whether the thickness Tₚ of an internal electrode partially facing portion 13 in the stacking direction is smaller than the maximum thickness T₁ of a capacitance forming portion 12 in the stacking direction. First, the face perpendicular to the mounting face of the multilayer ceramic capacitor 100 is polished to expose the vicinity of the centroid of a via conductor 23a. This polishing may be performed on a multilayer ceramic capacitor 100 embedded in resin. Next, the polished face in which the via conductor 23a is exposed is inspected using an optical microscope or a scanning electron microscope (SEM), and an image is obtained in which the boundary between the via conductor 23a and the ceramic layers 21, as well as the mounting face 11 and the opposite face, are in the same field of view, as shown in FIG. 4. In FIG. 4, the terminal electrodes 40a are omitted to make it easier to see the positions of the capacitance forming portion 12 and the internal electrode partially facing portion 13. Next, in the acquired image, the internal electrodes 22 (22a, 22b) are inspected in the vicinity of the via conductor 23a, and line segment e is drawn connecting the end points of the internal electrodes 22b not connected to the via conductor 23a. If the endpoints of the internal electrodes 22b do not lie on a specific line segment, then the line segment that is closest to each endpoint is drawn as line segment e. Line segment e may be drawn on both sides of the via conductor 23a, or only on one side, depending on the arrangement of internal electrodes 22 (22a, 22b). Next, the region which is located on the side of the via conductor 23a of the line segment e, where the internal electrodes 22 (22a, 22b) are formed, including the via conductor 23a is defined as the internal electrode partially facing portion 13. Also, the region which is located on the opposite side to the via conductor 23a of the line segment e and internal electrodes are formed is defined as capacitance forming portions 12. Next, in a region defined as a capacitance forming portion 12, the longest line segment connecting the mounting face 11 and the opposite face and parallel to a line segment e that defines the boundary with the internal electrode portion 13, is determined as line segment t₁. The value obtained by dividing the length of line segment t₁ by the magnification factor of the microscopic image is used as the maximum thickness T₁ of the capacitance forming portion 12 in the stacking direction. Next, at any point in a region defined as an internal electrode partially facing portion 13, a line segment tₚ is drawn that is parallel to line segment t₁ and connects the surface of the cover portion 31 that forms the mounting face 11 with the surface of the cover portion 31 that forms the opposite face, and the value obtained by dividing the length of the line segment tₚ by the magnification factor of the microscopic image is defined as the thickness Tₚ of the internal electrode partially facing portion 13 at that point in the stacking direction. Then, the relationship Tₚ<T₁ is established for the entire internal electrode partially facing portion 13, and it is determined that the thickness Tₚ of the internal electrode partially facing portion 13 in the stacking direction is smaller than the maximum thickness T₁ of the capacitance forming portion 12 in the stacking direction. This process was performed near via conductor 23a, but it goes without saying that this process can also be performed near via conductor 23b, which has a different polarity.

In an internal electrode partially facing portion 13, when the minimum value of the thickness Tₚ in the stacking direction is T₂, the value of T₁−T₂ is preferably 0.2 μm or more and 40 μm or less, more preferably 0.5 μm or more and 35 μm or less, and even more preferably 1 μm or more and 30 μm or less. The effect of suppressing the decrease in capacitance described above is significant when the T₁−T₂ value is 0.2 μm or more. Meanwhile, the decrease in mechanical strength caused by the decrease in the thickness of the element body 10 can be suppressed when the T₁−T₂ value is 40 μm or less.

In an internal electrode partially facing portion 13, when the minimum value of the thickness Tₚ in the stacking direction is T₂, the value of {(T₁−T₂)/T₁}×100, that is, the percentage of the difference between the maximum thickness T₁ of the capacitance forming portion 12 and the minimum thickness T₂ of the internal electrode partially facing portion 13 over the maximum thickness of the capacitance forming portion 12, is preferably 0.2% or more and 40% or less, more preferably 0.5% or more and 35% or less, and even more preferably 1% or more and 30% or less. The effect of suppressing the decrease in electrostatic capacitance is significant when the value of {(T₁−T₂)/T₁}×100 is 0.2% or more. Meanwhile, the decrease in mechanical strength due to the decrease in the thickness of the element body 10 can be suppressed when the value of {(T₁−T₂)/T₁}×100 is 40% or less.

In an internal electrode partially facing portion 13, it is preferable to increase the value of Tₚ as the capacitance forming portion 12 is approached from the via conductor 23 from the standpoint of suppressing the decrease in the mechanical strength of the element body 10. Also, in the internal electrode partially facing portion 13, the shape of the mounting face 11, or the face opposite it, preferably has an increasing rising amount as the measuring point is approached from the via conductor 23 to the capacitance forming portion 12. This is thought to suppress a concentration of stress at specific points because the direction of the normal differs depending on the point on a surface with this shape. If either the mounting face 11, or the face opposite it, has this shape, the decrease in the mechanical strength of the element body 10 is significantly suppressed. However, it is the most preferable that both mounting face 11 and the opposite surface have this shape from the standpoint of suppressing the decrease in the mechanical strength of the element body 10.

The thickness of the element body 10, which is obtained by subtracting the thickness of the terminal electrodes 40 (40a, 40b) from the T-direction dimension of the multilayer ceramic capacitor 100, is, for example, 20 μm or more and 200 μm or less, and preferably 30 μm or more and 180 μm or less.

The following is a detailed description of each component that constitutes the multilayer ceramic capacitor 100 in the first embodiment.

The ceramic layers 21 are formed of a ceramic. The composition of the ceramic is not particularly limited, as long as it forms a dense ceramic layer 21 during simultaneous firing with the internal electrodes 22 described below, and can be selected as appropriate depending on the characteristics required of the multilayer ceramic capacitor. Examples of ceramic compositions include those with barium titanate (BaTiO₃) as the main component, those with strontium titanate (SrTiO₃) as the main component, and those with a perovskite-type structure Ba_{1-x-y}CaₓSr_{y}Ti_{1-z}Zr_{z}O₃ as the main component. The ceramic may contain additive elements in addition to the main components mentioned above. Examples of additive elements include at least one selected from Mo, Nb, Ta, W, Mg, Mn, V, and Cr, rare earth elements (Y, Sm, Eu, Gd, Tb, Dy, Ho, Er, Tm, and Yb), and Co, Ni, Li, B, Na, K, and Si. The additive element may be included in the form of a compound, such as an oxide, nitride, or carbide, or it may be included as the element in its pure form. In addition, the additive elements may be present in a solid solution with the main component mentioned above, or may form a different phase with the element that constitutes the main component or another additive element.

### Internal Electrodes

The internal electrodes 22 (22a, 22b) are composed primarily of metal. There are no particular restrictions on the type of metal, and nickel (Ni), copper (Cu), palladium (Pd), platinum (Pt), silver (Ag), gold (Au), or alloys of these metals can be used. Among these, those with nickel (Ni) as the main component element are preferred because of their high heat resistance, which allows the firing temperature to be increased during firing together with the ceramic layers 21 to form dense ceramic layers 21, and because they are relatively inexpensive. In this document, the term “main component element” refers to the element with the highest content, expressed as an atomic percentage (at %).

In addition to metal, the internal electrodes 22 (22a, 22b) may also contain ceramic particles having a composition similar to that of the ceramic that constitutes the ceramic layers 21, or glass components.

### Protective Portion

The protective portion 30 has the function of protecting the ceramic layers 21 and internal electrodes 22. The material in the protective portion 30 is not limited as long as it has high electrical insulation properties and low permeability to moisture and other degradation factors. From the standpoint of ensuring uniform shrinkage during firing when manufacturing the multilayer ceramic capacitor 100, and relieving internal stress inside the multilayer ceramic capacitor 100, the main component of the protective portion 30 is preferably the same as the ceramic forming the ceramic layers 21.

### Via Conductors

Like the internal electrodes 22 (22a, 22b), the via conductors 23 (23a, 23b) are made primarily of metal. The metals that can be used are the same as those used in the internal electrodes 22 (22a, 22b) mentioned above. The composition of the via conductors may be different from that of the internal electrodes 22 (22a, 22b), but is preferably the same as that of the internal electrodes 22 (22a, 22b). By making the composition of the via conductors (23a, 23b) and the internal electrode 22 (22a, 22b) the same, the degree of shrinkage caused by firing during the manufacture of the multilayer ceramic capacitor 100 is uniform, which helps to suppress deformation, and the resistivity of the conductive paths of the multilayer ceramic capacitor 100 is uniform, which helps to suppress localized heat generation during use.

The diameter of the via conductors 23 (23a, 23b) is not particularly limited, but from the standpoint of reducing electrical resistance and suppressing heat generation during circuit operation while maintaining the capacitance of the multilayer ceramic capacitor 100, the diameter is preferably 5 μm or more and 100 μm or less, and more preferably 10 μm or more and 50 μm or less.

### Terminal Electrodes

The material of the terminal electrodes 40 (40a, 40b) is not limited as long as the material has electrical conductivity. Examples of materials include metals such as nickel (Ni), copper (Cu), tin (Sn), palladium (Pd), platinum (Pt), silver (Ag), and gold (Au), alloys containing any of these as the main component, and electrically conductive resins.

The terminal electrodes 40 (40a, 40b) may be composed of a base conductor 41 in contact with the element body 10 and a plated conductor 42 formed on the surface of the base conductor 41. Terminal electrodes 40 (40a, 40b) with this structure can improve adhesion of the element body 10 with the base conductor 41, and improve the solder wettability when mounted on the circuit board using the plated conductor 42.

An example of a material for the base conductor 41 is Ni. The thickness of the base conductor 41 can be 0.1 μm or more and 10 μm or less, and is preferably 0.5 μm or more and 5 μm or less.

The plated conductor 42 may be formed with a single layer or with multiple layers. When multiple layers are formed in the plated conductor 42, two to four layers is preferred. In one example of the materials and structure of the plated conductor 42, a structure is formed in the order Cu, Ni, and Sn. The thickness of the plated conductor 42 can be 1 μm or more and 20 μm or less, and 3 μm or more and 10 μm or less is preferred.

### Second Embodiment

In another embodiment (second embodiment) of the multilayer ceramic capacitor in the first aspect of the invention, the outer edge of the stack and the outer edge of the via conductors may overlap in the cross-section parallel to the stacking direction passing through the via conductors. An example of such a multilayer ceramic capacitor 200 is shown in FIG. 5. In the case of this multilayer ceramic capacitor 200, because the area of an internal electrode partially facing portion 13 in the plane perpendicular to the stacking direction can be reduced and the area of the capacitance forming portion 12 can be increased, a larger electrostatic capacitance can be advantageously obtained.

### Third Embodiment

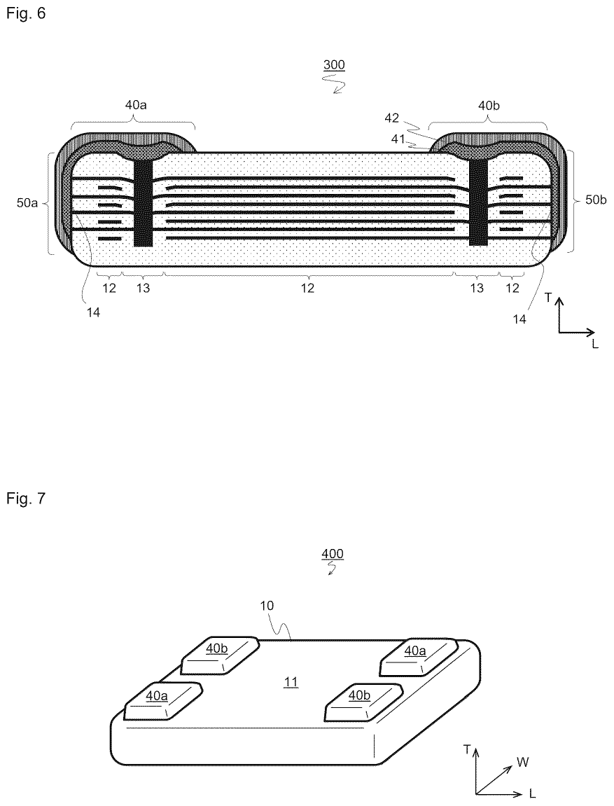

In another embodiment (third embodiment) of the multilayer ceramic capacitor in the first aspect of the invention, the internal electrodes are drawn out on a face perpendicular to the mounting face, and external electrodes are placed on the face from which the internal electrodes are drawn out (draw-out face), so that the internal electrodes are electrically connected to each other via the external electrodes. An example of a multilayer ceramic capacitor 300 in the third embodiment is shown in FIG. 6. FIG. 6 shows an example in which two faces opposite each other are used as draw-out faces 14, but the number of draw-out faces is not limited to this example. FIG. 6 shows an example of terminal electrodes 40 (40a, 40b) extending to draw-out face 14 forming external electrodes 50 (50a, 50b), but external electrodes 50 (50a, 50b) may be formed separately from terminal electrodes 40 (40a, 40b). Also, in FIG. 6, there are regions on both the left and right ends of the multilayer ceramic capacitor 300 in which only a portion of the internal electrodes overlap in the stacking direction, but because there are no via conductors arranged adjacent to these areas, they do not correspond to the internal electrode partially facing portions as defined in the present invention. In the multilayer ceramic capacitor 300, the current flowing through the internal electrodes 22 (22a, 22b) is divided between via conductors 23 (23a, 23b) and external electrodes 50 (50a, 50b), resulting in smaller current flowing through individual via conductors 23 (23a, 23b) and external electrodes 50 (50a, 50b). This reduces heat generation during operation.

### Fourth Embodiment

In another embodiment (the fourth embodiment) of the multilayer ceramic capacitor in the first aspect of the invention, the number of terminal electrodes located on the mounting face is four or more, and each terminal electrode has a different polarity from the terminal electrodes that are closest to it on the mounting face. An example of the third embodiment of a multilayer ceramic capacitor 400 is shown in FIG. 7. While FIG. 7 shows an example in which the number of terminal electrodes 40 arranged on the mounting face 11 is four, the number of terminal electrodes arranged on the mounting face is not limited to this example. Because the multilayer ceramic capacitor 400 is configured so that the direction of the current flowing through the via conductors (not shown) electrically connected to each terminal electrode 40 (40a, 40b) is in the opposite direction between conductors that are nearest to each other, the magnetic fields generated by the current cancel each other out, reducing the equivalent series inductance (ESL). These effects are more pronounced when the multilayer ceramic capacitor 400 has a mounting face 11 that is nearly square in shape, that is, when the value of W/L, which is the ratio of W to L, is between 0.8 and 1, where, among the two faces parallel to the stacking direction of the stack and facing each other, one spacing, or dimension in the L direction, is L μm, and the other spacing, or dimension in the W direction, is W μm (provided L≥W).

### Method for Manufacturing Multilayer Ceramic Capacitor

A multilayer ceramic capacitor in the first aspect of the present invention can be manufactured by the procedure described below.

### (A) Preparation of Ceramic Powder

First, the ceramic powder is prepared. Commercially available ceramic powders can be used if appropriate. When the ceramic powder is prepared by the user, raw powder materials including their constituent elements are mixed at a predetermined ratio and pre-fired (provisionally fired). Additives such as the additive elements and firing aids may be added when mixing the raw powder materials at predetermined ratios, or the additives may be included to the powder after provisional firing.

### (B) Preparation of the Green Sheet

Next, the ceramic powder is mixed with a binder and dispersant to prepare a slurry, which is then formed into a sheet to obtain a green sheet.

The binder used should be the one that can maintain the shape of the green sheet, and that can volatilize without leaving behind carbon or other residues in the binder removal step prior to firing. Examples of binders that can be used include polyvinyl alcohol-based, polyvinyl butyral-based, cellulose-based, urethane-based, and vinyl acetate-based binders. The amount of binder used is not limited, but since it is removed in a subsequent step, the amount of binder used is preferably minimized to the extent that the desired moldability and shape retention can be obtained, in order to reduce raw material costs.

The dispersant used should be the one that can keep the previously fired powder and the binder from agglomerating and should be easily removed by volatilization or other means after formation of the green sheet described below. Examples of dispersants that can be used include water and alcohol-based solvents.

Components that adjust the properties of the slurry, such as dispersants, plasticizers, and thickeners, may be added to the slurry.

The method used to mix the mixed powder with the binder and dispersant is not limited as long as each component is uniformly mixed and impurities are kept from being mixed in. One example is ball mill mixing.

Methods that can be used to form the prepared slurry into a sheet to obtain a green sheet include any method common in the art, such as the doctor blade method and the die coating method.

### (C) Formation of the Internal Electrode Pattern

Next, an internal electrode pattern containing metal is formed on the green sheet. The internal electrode pattern can be formed by printing or coating internal electrode paste in a predetermined pattern, or by forming a metal film in a predetermined pattern by vapor deposition or sputtering deposition. The internal electrode pattern should be formed leaving a sufficient margin to ensure electrical insulation where there is no contact with the via conductor pattern formed later. This margin forms the internal electrode partially facing portion in the element body obtained in the firing process described below.

When forming an internal electrode pattern using an internal electrode paste, the internal electrode paste is obtained by mixing metal particles with a vehicle in a three-roll mill. In addition to the components mentioned above, the internal electrode paste may also contain glass frit or ceramic powder.

The type and amount of binder and solvent included in the vehicle are not limited, and are preferably selected as appropriate after taking into consideration the viscosity of the internal electrode paste, ease of handling, and compatibility with the green sheet.

Printing of the internal electrode paste on the green sheet can be performed, for example, using a screen mask with a predetermined internal electrode pattern. During printing, a space, that will become the margin portion when made into a multilayer ceramic capacitor, can be left.

### (D) Preparation of the Green Stack

Next, green sheets with internal electrode patterns are stacked in a predetermined number of layers, and the green sheets are pressure-bonded to obtain a green stack. Stacking and pressure bonding can be performed using any method common in the art, such as pressing the stacked green sheets together in the stacking direction while heating, and thermo-compression bonding the green sheets together by the action of the binder. In this case, by pressing using a mold with protrusions at positions corresponding to the internal electrode partially facing portions, the thickness of the internal electrode partially facing portions can be made thinner than that of the capacitance forming portions.

When performing stacking and pressure bonding, a green sheet may be added to the end in the stacking direction to serve as a cover portion when made into a multilayer ceramic capacitor. At this time, the green sheet that is added may have the same or a different composition from the green sheets on which an internal electrode pattern has been printed. From the standpoint of matching the shrinkage rate during firing, the composition of the green sheet that is added is preferably the same or similar to the composition of the green sheets on which the internal electrode precursors have been arranged.

### (E) Formation of the Via Conductor Pattern

Next, holes are formed in the green stack, and the holes are filled with conductive paste to form a via conductor pattern. A method common in the art such as a drill or laser can be used to form the holes. Among these, the use of a laser is preferred because of its ability to form smooth machined surfaces. A method common in the art such as injection with a syringe or printing with a metal mask can be used to fill the holes with conductor paste. Among these, printing with a metal mask is preferred because of its superiority in filling small-diameter holes. As for the components in the conductor paste, the same as those in the internal electrode paste can be used, and the amount of each component should be determined after taking into consideration the hole filling properties.

### (F) Formation of the Terminal Electrode Pattern

Next, a terminal electrode pattern is formed on at least one of the faces perpendicular to the stacking direction (mounting face) in the green stack. At this time, a green sheets which become the cover portion when made into a multilayer ceramic capacitor may be pressure bonded to the face on which the terminal electrode pattern is not formed so as to cover the via conductor pattern. The terminal electrode pattern can be formed by printing or applying terminal electrode paste or by forming a metal film by vapor deposition or sputtering deposition. At this time, the terminal electrode pattern may be formed using a mask with a predetermined pattern, or may be formed out of a paste film or metal film over the entire mounting face of the green stack, by removing the portions outside of the terminal electrode pattern. Face milling and barrel polishing can be used to remove the portions outside of the terminal electrode pattern. When terminal electrode paste is used to form the terminal electrode pattern, the same components as those in the internal electrode paste described above can be used, and the amount of each component is determined so that a uniform pattern can be obtained at a predetermined thickness.

### (G) Preparing Pre-Fired Chips

Next, the green stack is separated into units in the shape of individual multilayer ceramic capacitors to obtain chips prior to firing. Means commonly used to separate a green stack into individual capacitors include dicing saws and laser cutting machines. After the green stack has been separated into units to form a face on which the internal electrode precursor is exposed, the face may be coated with a material for forming a margin portion to complete the pre-fired chips.

### (H) Removing the Binder

The resulting pre-fired chips are then heated to volatilize and remove the binder. Heating conditions should be set as appropriate after taking into consideration the amount and volatilization temperature of the binder. One example is to hold temperatures from 200° C. to 500° C. for 5 to 20 hours in a nitrogen (N₂) atmosphere.

### (I) Firing the Pre-Fired Chips

Next, the pre-fired chips with the binder removed are heated to a predetermined temperature for firing. When setting the firing conditions, the firing properties of the ceramic powder and the heat and oxidation resistance of the metals in the internal electrode pattern, via conductor pattern, and terminal electrode pattern are preferably taken into consideration. Examples of firing conditions include holding the chips at 1100° C. to 1400° C. for 10 minutes to 2 hours in a reducing atmosphere of nitrogen (N₂), hydrogen (H₂), and water vapor (H₂O). After firing, re-oxidation treatment may be performed in a nitrogen (N₂) gas atmosphere or in a low-oxygen atmosphere kept at 600° C. to 1000° C.

The fired body thus obtained may be used as a multilayer ceramic capacitor as is, or it may be used as a multilayer ceramic capacitor after a conductive layer has been formed on the surface of the terminal electrode pattern by plating.

### Circuit Board

The circuit board in the second aspect of the invention has a mounted multilayer ceramic capacitor in the first aspect. This circuit board can be reliably installed in a small space because the multilayer ceramic capacitor is thin and suppresses the decrease in electrostatic capacitance.

The following technologies are also disclosed in the present specification.

### Addendum 1

A multilayer ceramic capacitor, comprising:
a cuboid element body having
   a stack formed with alternating ceramic layers and internal electrodes made primarily of metal,
   a protective portion covering a surface of the stack, and
   a plurality of via conductors arranged so as to pass through the ceramic layers in the stacking direction of the stack, electrically connected to the internal electrodes, and having at least one end portion reaching the surface of the protective portion, and
a plurality of terminal electrodes arranged on at least a mounting face, which is the face that faces the circuit board when the multilayer ceramic capacitor is mounted on the circuit board, among faces that form the surfaces of the element body, and connected electrically to the via conductors,
   wherein the element body includes
a capacitance forming portion, which is a region in which internal electrodes of different polarities overlap in the stacking direction, and
an internal electrode partially facing portion formed by a region in which the internal electrodes of the same polarity overlap in the stacking direction, and the via conductor arranged adjacent to this region, and
   the thickness Tₚ of the internal electrode partially facing portion in the stacking direction is less than the maximum thickness T₁ of the capacitance forming portion in the stacking direction.

### Addendum 2

The multilayer ceramic capacitor according to (Addendum 1), wherein the spacing of the internal electrode partially facing portion between the mounting face and the face opposite this increases as the capacitance forming portion is approached from the formation position of the via conductor.

### Addendum 3

The multilayer ceramic capacitor according to (Addendum 1) or (Addendum 2), wherein the value of T₁−T₂ is 0.2 μm or more and 40 μm or less, where T₂ is the minimum value of Tₚ.

### Addendum 4

The multilayer ceramic capacitor according any of (Addendum 1) to (Addendum 3), wherein the value of {(T₁−T₂)/T₁}×100, which is the percentage of the difference between T₁ and T₂ relative to T₁, is 0.2% or more and 40% or less, where T₂ is the minimum value of Tₚ.

### Addendum 5

The multilayer ceramic capacitor according any of (Addendum 1) to (Addendum 4), wherein the dimension in the stacking direction is less than 100 μm.

### Addendum 6

A circuit board carrying the multilayer ceramic capacitor according to any one of (Addendum 1) to (Addendum 5).

### INDUSTRIAL APPLICABILITY

The present invention is able to provide a thin multilayer ceramic capacitor with suppressed electrostatic capacitance degradation. In addition to being highly reliable, such multilayer ceramic capacitors can be placed in small spaces, and so are useful in terms of placing fewer restrictions on circuit board design.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A multilayer ceramic capacitor, comprising:
a cuboid element body having
a stack formed with alternating ceramic layers and internal electrodes made primarily of metal,
a protective portion covering a surface of the stack, and
a plurality of via conductors arranged so as to pass through the ceramic layers in the stacking direction of the stack, electrically connected to the internal electrodes, and having at least one end portion reaching the surface of the protective portion, and
a plurality of terminal electrodes arranged on at least a mounting face, which is the face that faces the circuit board when the multilayer ceramic capacitor is mounted on the circuit board, among faces that form the surfaces of the element body, and connected electrically to the via conductors,
wherein the element body includes
a capacitance forming portion, which is a region in which internal electrodes of different polarities overlap in the stacking direction, and
an internal electrode partially facing portion formed by a region in which the internal electrodes of the same polarity overlap in the stacking direction, and the via conductor arranged adjacent to this region, and
the thickness Tₚ of the internal electrode partially facing portion in the stacking direction is less than the maximum thickness T₁ of the capacitance forming portion in the stacking direction.

2. The multilayer ceramic capacitor according to claim 1, wherein the Tₚ value of the internal electrode partially facing portion increases as the capacitance forming portion is approached from the formation position of the via conductor.

3. The multilayer ceramic capacitor according to claim 1, wherein the value of T₁−T₂ is 0.2 μm or more and 40 μm or less, where T₂ is the minimum value of Tₚ.

4. The multilayer ceramic capacitor according to claim 1, wherein the value of {(T₁−T₂)/T₁}×100, which is the percentage of the difference between T₁ and T₂ relative to T₁, is 0.2% or more and 40% or less, where T₂ is the minimum value of Tₚ.

5. The multilayer ceramic capacitor according to claim 1, wherein the dimension in the stacking direction is less than 220 μm.

6. The multilayer ceramic capacitor according to claim 1, wherein the dimension in the stacking direction is less than 100 μm.

7. A circuit board carrying the multilayer ceramic capacitor according to claim 1.
